(19) United States
(12) Patent Application Publication
(10) Pub. No.: US 2023/0067995 A1
(43) Pub. Date: Mar. 2, 2023

(54) DISPLAY APPARATUS

(71) Applicants: Beijing BOE Display Technology Co., Ltd., Beijing (CN); BOE TECHNOLOGY GROUP CO., LTD., Beijing (CN)

(72) Inventors: Danjuan LIU, Beijing (CN); Rui GUO, Beijing (CN); Hetao WANG, Beijing (CN); Shou LI, Beijing (CN); Jian ZHANG, Beijing (CN); Jianting WANG, Beijing (CN); Hengyu YAN, Beijing (CN); Bochang WANG, Beijing (CN)

(21) Appl. No.: 17/918,994

(22) PCT Filed: Feb. 19, 2021
(86) PCT No.: PCT/CN2021/076887

§ 371 Date: Oct. 14, 2022

(30) Foreign Application Priority Data
Apr. 16, 2020 (CN) 202020565517.6

(51) Int. Cl. H05K 5/00; H05K 5/02; H05K 9/00

(52) U.S. Cl. CPC H05K 5/0008; H05K 5/0018; H05K 5/0217; H05K 9/0067

(57) ABSTRACT

A display apparatus includes a housing; a back plate on the housing; a metal bezel clamped with the back plate at a side of the back plate; a display module and a display driving board on a side of the back plate away from the housing. An insulating material layer is provided between the back plate and the display driving board, which directly increases an impedance of a path for static electricity from the back plate to the display driving board; a side of the display module is fixed to the metal bezel by an insulating member, indirectly increasing an impedance of a path of the static electricity entering the display driving board through the display module. Therefore, most of the static electricity is discharged through other paths with small impedance, so that the static electricity less enters a signal ground plane.

### CROSS REFERENCE TO RELATED APPLICATIONS

The present application claims the priority of the Chinese Patent Application No. 202020565517.6 filed to the Chinese Patent Office on Apr. 16, 2020, entitled “display apparatus”, the content of which is incorporated herein by reference in its entirety.

### TECHNICAL FIELD

The present disclosure relates to the field of display technology, and in particular to a display apparatus.

### BACKGROUND

Static electricity is an objective natural phenomenon, and is generated in various ways, such as contact, friction, and induction between electric appliances. The static electricity has characteristics of long-time accumulation, high voltage, low power, small current and short action time. The static electricity causes serious harm in multiple fields. Electricity by friction and human body static electricity are two major hazards in the electronic industry, and often cause unstable operation and even damage of electronic and electric products.

A general complete machine electrostatic (ESD) standard is an IEC 61000-4-2 standard in which ESD requirements are at a B grade (CLASS B). With the development of society, the living standard of people is continuously improved, requirements on a product become higher and higher with experience requirements of a customer. For a outdoor product or a rail transit product, the original CLASS B cannot meet the requirements of a customer on a display product, the current requirements on a product is improved to be at an A grade (CLASS A) from the CLASS B. That is, a screen flash should not exist in the display product. The upgrading of the grade of the ESD requirements causes the problem that ESD test fail (NG) occurs in a plurality of sorts of complete machine products. In order to meet test requirements of the customer and assist the customer to successfully pass the ESD test for the product, an ESD resistance of the complete machine needs to be improved.

### SUMMARY

An embodiment of the present disclosure provides a display apparatus, including: a housing; a back plate above the housing; a metal bezel clamped with the back plate at a side of the back plate; a display driving board on a side of the back plate away from the housing; an insulating material layer between the back plate and the display driving board; and a display module on a side of the back plate away from the housing, and fixed to the metal bezel through an insulating member at a side of the display module.

In a possible implementation, in the display apparatus provided by the embodiment of the present disclosure, the insulating material layer is a first insulating mylar layer.

In a possible implementation, in the display apparatus provided by the embodiment of the present disclosure, the insulating member is a first conductive screw having an insulating varnish on a surface thereof.

In a possible implementation, in the display apparatus provided by the embodiment of the present disclosure, an insulating varnish is on a surface of the housing away from the back plate.

In a possible implementation, in the display apparatus provided by the embodiment of the present disclosure, an insulating varnish is on a surface of the metal bezel facing the display module.

In a possible implementation, in the display apparatus provided by the embodiment of the present disclosure, an insulating varnish is on a surface of the metal bezel away from the display module.

In a possible implementation, the display apparatus provided by the embodiment of the present disclosure further includes: a conductive foam between the housing and the back plate.

In a possible implementation, the display apparatus provided by the embodiment of the present disclosure further includes: a back cover which completely covers the display driving board and is clamped with the metal bezel, wherein an insulating varnish is provided on a surface of the back cover away from the display driving board.

In a possible implementation, the display apparatus provided by the embodiment of the present disclosure further includes: a second insulating mylar layer on a side of the display driving board facing the back cover.

In a possible implementation, the display apparatus provided by the embodiment of the present disclosure further includes: an aluminum foil which completely covers the back cover, wherein a surface of the aluminum foil close to the display driving board is in contact with a surface of the back plate away from the housing.

In a possible implementation, the display apparatus provided by the embodiment of the present disclosure further includes: a system board above the housing; and riveting columns for fixing the system board and the housing.

In a possible implementation, the display apparatus provided by the embodiment of the present disclosure further includes: second conductive screws for fixing the housing and the back plate, a ground wire electrically connected to the display driving board and the system board, respectively, and electrostatic isolating devices, each of which is connected between a corresponding one of the second conductive screws and the ground wire.

In a possible implementation, in the display apparatus provided by the embodiment of the present disclosure, each electrostatic isolating device includes: one of a capacitor, a resistor and a magnetic bead or a combination formed by any parallel connection thereof.

### BRIEF DESCRIPTION OF DRAWINGS

FIG. 1 is a schematic diagram illustrating a standard waveform of electrostatic discharge in the related art;

FIG. 2 is a schematic diagram of a structure of a complete machine in the related art;

FIG. 3 is a schematic block diagram of an ESD discharge path in a complete machine in the related art;

FIG. 4 is a simplified schematic diagram of an ESD discharge path in a complete machine in the related art;

FIG. 5 is a schematic diagram illustrating normal transmission of an ESD signal;

FIG. 6 is a schematic diagram illustrating a reflection of an ESD signal;

FIG. 7 is a schematic diagram of a structure of a complete machine according to an embodiment of the present disclosure;

FIG. 8 is an enlarged structural view of a region P in FIG. 7;

FIG. 9 is a schematic diagram illustrating an insulation process for a display driving board according to an embodiment of the present disclosure;

FIG. 10 is a schematic diagram of a geometric model of a transfer belt in the related art;

FIG. 11 is a schematic block diagram of an ESD discharge path in a complete machine according to the embodiment of the present disclosure;

FIG. 12 is a simplified schematic diagram of an ESD discharge path in a complete machine according to the embodiment of the present disclosure;

FIG. 13 is a comparison graph illustrating fluctuations of a signal at a signal ground plane according to an embodiment of the present disclosure and a signal at a signal ground plane in the related art;

FIG. 14 is a schematic diagram illustrating replacement of a conventional conductive screw with a conductive screw plated with an insulating varnish for an insulating member according to an embodiment of the present disclosure;

FIG. 15 is a schematic diagram illustrating an insulation process for a housing according to an embodiment of the present disclosure;

FIG. 16 is a schematic diagram illustrating an insulation process for a metal frame according to an embodiment of the present disclosure;

FIG. 17 is a schematic diagram illustrating another insulation process for a display driving board according to an embodiment of the present disclosure;

FIG. 18 is a schematic diagram illustrating how to mount a system board according to an embodiment of the present disclosure; and

FIG. 19 is a schematic diagram illustrating a connection between a signal ground plane and the ground according to an embodiment of the present disclosure.

### DETAIL DESCRIPTION OF EMBODIMENTS

In order to make objects, technical solutions and advantages of the embodiments of the present disclosure more apparent, the technical solutions of the embodiments of the present disclosure will be clearly and completely described below with reference to drawings of the embodiments of the present disclosure. Dimensions and shapes of various elements in the drawings are not to scale and are merely intended to illustrate the present disclosure. Like or similar reference numerals refer to like or similar elements or elements having like or similar functions throughout the description. Obviously, the described embodiments are only a few, not all, embodiments of the present disclosure. All other embodiments, which can be derived by a person skilled in the art from the described embodiments of the present disclosure without inventive steps, are intended to be within the protection scope of the present disclosure.

In addition, unless defined otherwise, technical or scientific terms used herein shall have the ordinary meaning as understood by a person skilled in the art to which the present disclosure belongs. The terms “first”, “second”, and the like used in the description and the claims of the present disclosure are not intended to indicate any order, quantity, or importance, but rather are used for distinguishing one element from another. The term “comprising”, “including”, or the like, means that the element or item preceding the term contains the element or item listed after the term and its equivalent, but does not exclude other elements or items. The terms “inner”, “outer”, “upper”, “lower”, and the like are used only for indicating relative positional relationships, and when the absolute position of an object being described is changed, the relative positional relationships may also be changed accordingly.

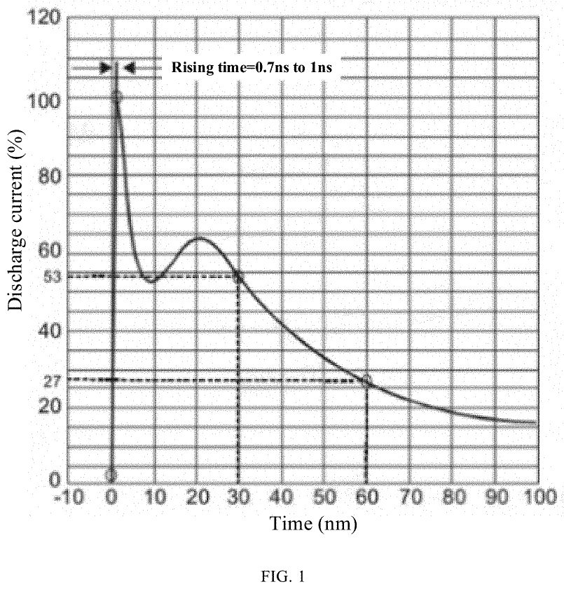

An ESD standard waveform is shown in FIG. 1 according to a specification of the IEC 61000-4-2 standard for ESD. As shown in FIG. 1, an ESD main signal is a high-frequency signal with a pulse width in an order of magnitude of nanosecond (ns). Generally speaking, when a wavelength of a transmission signal having a highest frequency in a transmission cable is less than 10 times a length of the cable, the transmission cable may be regarded as a transmission line, an impedance of which needs to be calculated based on an impedance of a high-frequency-signal transmission line. The ESD signal is an instantaneous discharge, generating an interference waveform which may be regarded as a signal with a high frequency in an order of magnitude of hundred MHz. A transmission path, i.e., a discharge path, is longer, and is through a whole housing from a discharge point to a ground point, including through a gap and a circuit board. A calculation equation for the wavelength is as follows:

λ=c/f Equation 1

where λ denotes a wavelength, c denotes the speed of light (specifically 3*10⁸ m/s), and f denotes a frequency.

The wavelength of 3 m is derived according to the equation 1 by taking a high frequency signal of 100 MHz as an example. For a current complete machine of 30 inches or more, a length from the discharge point to the ground point is conservatively estimated to be 0.5 m, and thus, 0.5*10=5 m. Thus, the wavelength of 3 m is less than 10 times the length of the cable (i.e., the conservative estimate of 5 m). Therefore, the ESD discharge path is the common ground plane, but the generated ESD interference belongs to a high frequency signal so that the ground plane becomes a transmission line of the ESD signal. Therefore, an ESD discharge path having a minimum impedance should be analyzed by considering an impedance of each path according to the transmission line.

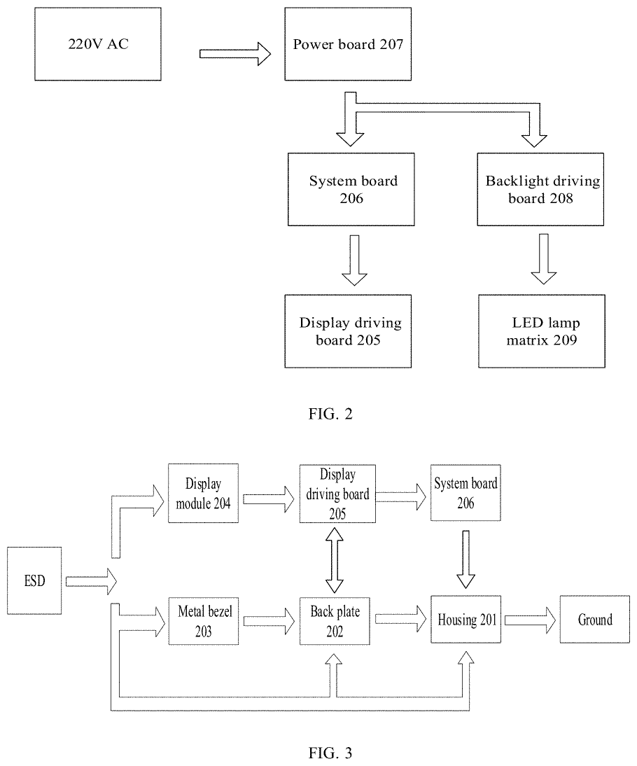

In the related art, a complete machine product generally includes a housing 201, a back plate 202, a metal bezel 203, a display module 204, a display driving board 205, a system board 206, a power board 207, a backlight driving board 208, and an LED lamp matrix (a matrix of LED lamps) 209, as shown in FIG. 2 and FIG. 3. When an ESD protection is designed for the complete machine product, the complete machine product is generally designed into a module with good electric conductivity. Specifically, the back plate 202 and the system board 206 are fixed on the housing 201 by conductive screws; the metal bezel 203 and the back plate 202 are clamped together; the display module 204 is locked with the metal bezel 203 by a conductive screw at a side of the display module 204; the display driving board 205 is electrically connected to the display module 204 to provide a driving signal for the display module 204; the system board 206 is electrically connected to the display driving board 205 to provide a timing control signal for the display driving board 205; the display driving board 205 is in sufficient contact with the back plate 202 through an exposed copper area for the electrostatic discharge; the display driving board 205 and the system board 206 all are connected to the ground wire, thereby forming a signal ground plane.

Due to the good electric conductivity, there is no significant difference in impedance among the housing 201, the back plate 202 and the display driving board 205, the ESD signal enters the complete machine through the housing 201 and may run around inside the complete machine. The ESD signal is not only discharged from the housing 201 to the ground, but also enters the display driving board 205 from the display module 204 through an ITO conductive layer and a ground silver paste point, and then a part of the ESD signal enters the back plate 202 through the exposed copper area from the display driving board 205 and then is introduced to the ground through the housing 201. The remaining part of the ESD signal is introduced to the system board 206 through a ground wire and then passes through a connection point between the system board 206 and the housing 201 and is introduced to the ground from the housing 201, as shown in FIG. 3.

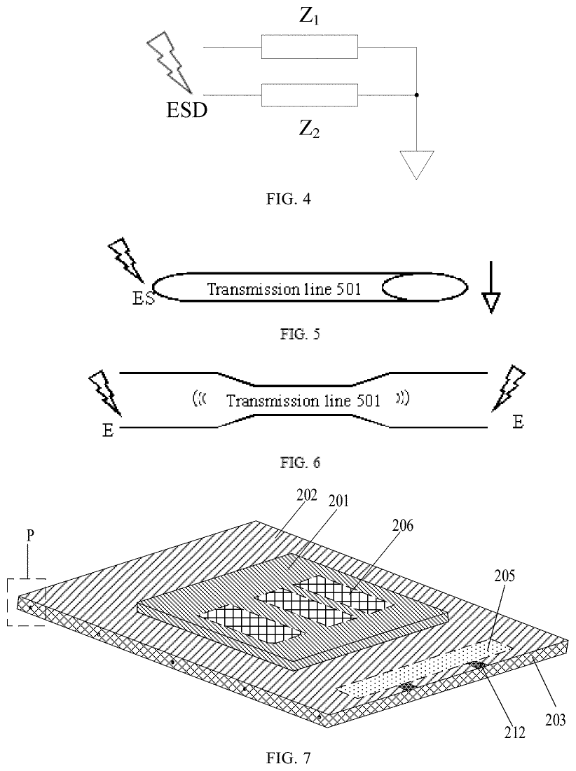

As can be seen from FIG. 3, the ESD discharge path designed for the complete machine in the related art includes two parallel paths, as shown in FIG. 4. Specifically, in FIG. 4, Z₁ represents an impedance on an ESD discharge path of “the display module 204→the display driving board 205→the system board 206→the housing 201→the ground”, and Z₂ represents an impedance on an ESD discharge path of “the metal bezel 203→the back plate 202→the housing 201→the ground”, so that there is no significant difference between the impedances of Z₁ and Z₂; and the two parts of the ESD signal will be discharged simultaneously through the two paths.

It is known that the ESD signal is discharged through an electrostatic gun in contact with the discharge point on the housing 201. Ideally, the ESD signal is introduced into the ground by directly entering the ground points from the housing 201, so that the complete machine system is not affected at all, which generally cannot be achieved. The ESD signal enters the housing 201 through the discharge point, passes to the metal bezel 203 from the housing 201, to the back plate 202 from the metal bezel 203, and is introduced to the ground from the back plate 202 connected to the housing 201 through the conductive screw, and such a discharge path will not greatly affect the complete machine system. A key point of affecting the complete machine system is the display driving board 205. The display driving board 205 is connected to the system board 206. Once a signal ground plane, as a reference, formed by the ground wires connected to the display driving board 205 and the system board 206, is greatly disturbed, the complete machine is affected in receiving a signal, which affects the display effect of the complete machine, and once the screen flash occurs, the human eye immediately notices it. Therefore, both the ESD interferences entering the display driving board 205 from the display module 204 and from the back plate 202 need to be concerned in the ESD protection design for the complete machine.

In order to prevent the device from being damaged by the ESD interference, the ESD signal is usually discharged by adding a transient diode (i.e., a TVS tube) to an input terminal of the display driving board 205 in the related art. However, a clamping voltage of the TVS tube is limited, a display input signal usually has a small voltage in a range from about 1.2V to about 1.8V, the TVS tube with an excellent performance may clamp the voltage to a value in a range from 7 V to 8V. It is not theoretically possible to cause the display input signal to be not affected by the ESD interference at all, and the TVS tube could only prevent the device from being unrecoverably damaged.

In view of above, the ESD signal is a high-frequency signal. If an impedance of a transmission channel (i.e., the transmission line 501) is kept consistent, as shown in FIG. 5, that is, the transmission channel has a small impedance and a short transmission path, the ESD signal is quickly introduced to the ground without reflection occurring on the signal ground plane, so that theoretically no screen flash caused by the ESD interference occurs. However, as shown in FIG. 6, in the transmission procedure, once a characteristic impedance discontinuity occurs in the transmission line 501, the ESD signal is reflected as the impedance changes, which produces a signal surge, so that the whole signal ground plane is disturbed and is greatly jittered, and the signal ground plane as the reference then changes, and the signal transmission is abnormal, and therefore, the screen flash may occur.

In the related art, the display driving board 205 and the system board 206 are connected to each other through the ground wire, which is usually a thin wire with a diameter of about 1 mm. The housing 201, the back plate 202 and the display driving board 205 each has a great area, so that there is a significant difference in impedance between the signal ground plane formed by the ground wires and the housing 201, the back plate 202 or the display driving board 205, and therefore, the ESD signal is easily reflected due to the impedance change to cause the flash screen. However, it is not easy to form an unobstructed continuous transmission channel on the discharge path of “the display driving plate 205→the system board 206→the housing 201→the ground”.

Through the above analysis, a preliminary conclusion can be drawn that a discharge path which has the greatest influence on determination of the ESD grade of the complete machine is the discharge path of “the display driving board 205→the system board 206→the housing 201→the ground”, because the signal ground plane formed by the ground wires connected to the display driving board 205 and the system board 206 is a reference plane of the whole system signal, a certain probability of signal abnormality occurs after the reference plane is interfered, so that the ESD grade is determined as the CLASS B, which cannot meet the current requirements, i.e., CLASS A.

In view of the above problems in the related art, an embodiment of the present disclosure provides a display apparatus, which may be: any product or component with a display function, such as a mobile phone, a tablet computer, a television, a display, a notebook computer, a digital photo frame, a navigator, an intelligent watch, a fitness wrist strap, and a personal digital assistant.

Specifically, an embodiment of the present disclosure provides a display apparatus, as shown in FIGS. 7 to 9, including: a housing 201, a back plate 202 on the housing 201, a metal bezel 203 clamped with the back plate 202 at a side of the back plate 202, and a display module 204 and a display driving board 205 on a side of the back plate 202 away from the housing 201.

An insulating material layer 210 is arranged between the back plate 202 and the display driving board 205.

The display module 204 is fixed to the metal bezel 203 through an insulating member 211 at a side of the display module 204.

As described above, the signal ground plane formed by the ground wires connected to the display driving board 205 is the reference plane of signals for the whole system of the display apparatus, a certain probability of signal abnormality occurs after the reference plane is interfered, so that the ESD grade is determined as the CLASS B, which cannot meet the current requirements, i.e., CLASS A, so that a discharge path which has the greatest influence on the determination of the ESD grade of the complete machine is the discharge path entering the display driving board 205. The ESD mainly enters the display driving board 205 through the back plate 202 and the display module 204 in the related art, so that the improvement is mainly made from the following two aspects in the display apparatus provided by the embodiment of the present disclosure.

In a first aspect, the insulating material layer 210 is arranged between the back plate 202 and the display driving board 205, which directly increases the impedance of the path for the ESD from the back plate 202 to the display driving board 205; specifically, as can be seen from a common geometric model of the transmission line, as shown in FIG. 10, a relationship of the ground wire of the display driving board 205 relative to the back plate 202 is equivalent to a relationship of a transmission band relative to an infinite metal board, so that the impedance should be calculated according to the transmission band parallel to the infinite metal board.

When w>3 h, the characteristic impedance is calculated by the following equation:

$${Z}_{0} = \frac{377}{\sqrt{{ε}_{r}}} * \frac{h}{w} \qquad Equation 2$$

where εᵣ represents a dielectric constant of the transmission band, w represents a bandwidth of the transmission band, and h represents a distance between the transmission band and the metal plate.

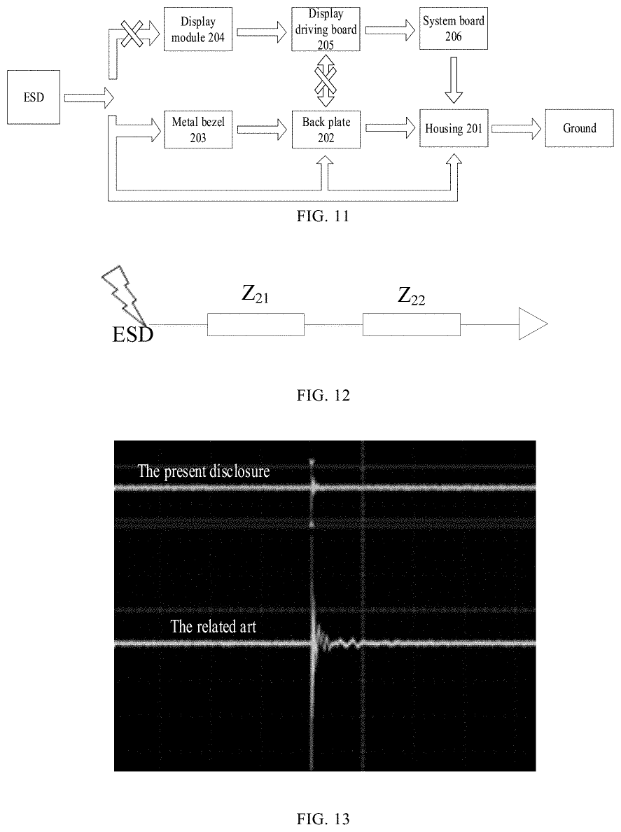

In the related art, the display driving board 205 is usually mounted close to the back plate 202, i.e. h is approximately 0, so w is much greater than 3 h. In a case where the insulating material layer 210 is added between the display driving board 205 and the back plate 202, which is equivalent to infinitely increasing h, h is directly proportional to the impedance, when other conditions are not changed, the impedance may be increased by increasing h. With the increased impedance, the discharge path through the back plate 202 and the display driving board 205 will not be a first choice for the ESD, and only a part of the ESD signal will be coupled into the signal ground plane through the housing 201, as shown in FIG. 11.

In a second aspect, the display module 204 and the metal bezel 203 are fixed together by the insulating member 211 at the side of the display module 204, so that the impedance of the path of the ESD entering the display module 204 through the metal bezel 203 is increased, which is equivalent to indirectly increasing the impedance of the path of the ESD entering the display driving board 205 through the display module 204. In this way, it is difficult for the ESD to enter the display driving board 205 through the display module 204, as shown in FIG. 11.

Therefore, most of the ESD is discharged through any other path with a small impedance, so that the ESD less enters the signal ground plane, thereby achieving a jitter of the ground reference plane which can be borne by a circuit, and improving the ESD protection grade. As can be seen from FIG. 11, the other path with a small impedance is a path of “the metal bezel 203→the back plate 202→the housing 201→the ground”. Based on this, the electrostatic discharge path in the display apparatus provided by the embodiment of the present disclosure has been changed to a serial discharge path (as shown in FIG. 12) from the parallel discharge paths (as shown in FIG. 4) in the related art, so that an amplitude of an interference of the ESD on the signal ground plane is greatly reduced, and the smaller ESD interference can be absorbed by the protection design for the circuit. In addition, it has been proved through experiments that in the display apparatus provided by the embodiment of the present disclosure, the ESD interference signal on the signal ground plane is changed to tens of volts of oscillation (as shown in FIG. 13) from hundreds of volts of oscillation in the related art. Thus, the improvement effect is obvious, and the ESD protection grade is improved.

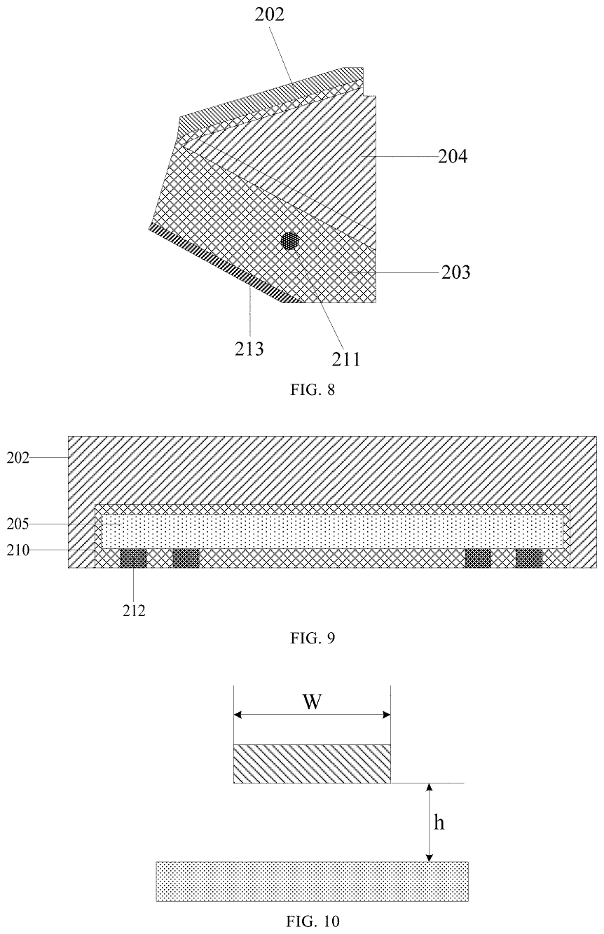

It should be noted that for the convenience of showing the back plate 202, only a convex portion of the housing 201 is shown in FIG. 7. In the actual product, the housing 201 further includes a planar portion covering the back plate 202. Generally, the display driving board 205 and chip on films (COFs) 212 are electrically connected to each other and located in a same plane, so that in practice, the insulating material layer 210 is further disposed between the back plate 202 and the chip on films 212, as shown in FIG. 9. In addition, in the display apparatus provided in the embodiment of the present disclosure, generally, a glass cover plate 213 may be located on a display side of the display module 204, as shown in FIG. 8; of course, other essential components of the display apparatus should be included, as understood by one of ordinary skill in the art, and are not described herein and should not be considered as limiting the present disclosure.

Optionally, in the above display apparatus provided in the embodiment of the present disclosure, the insulating material layer 210 may be a first insulating mylar sheet. The insulating mylar sheet itself has a super-strong insulating performance and also has an adhesive surface, so that the first insulating mylar sheet is simpler, more convenient and faster to be assembled on the display apparatus, thereby greatly shortening the production time, and improving the production efficiency.

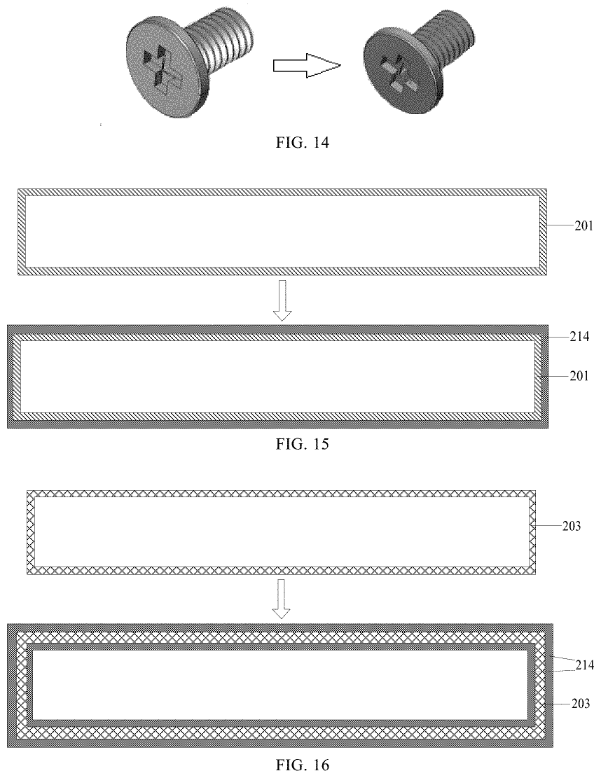

Optionally, in the above display apparatus provided by the embodiment of the present disclosure, as shown in FIG. 14, the insulating member 211 may be a first conductive screw having an insulating varnish on a surface thereof (in FIG. 14, a conductive screw in the related art is on the left side, and the first conductive screw having the insulating varnish on the surface thereof of the present disclosure is on the right side). The conductive screw is easily available and low in cost, and the insulating varnish on the surface of the conductive screw can completely isolate the conductive screw from the ESD, so that the ESD is prevented from being conducted by the conductive screw to the display module 204 due to the direct contact between the conductive screw and the ESD.

Optionally, in the display apparatus provided in the embodiment of the present disclosure, as shown in FIG. 15, the surface of the housing 201 away from the back plate 202 is provided with an insulating varnish 214. That is, by spraying the insulating varnish 214 on an outer surface of the housing 201 (in FIG. 15, a housing in the related art is on an upper side, and the housing having the insulating varnish on the surface thereof of the present disclosure is on a lower side), the ESD can be blocked outside the housing 201 to the maximum extent, thereby improving the ESD resistance.

Optionally, in the display apparatus provided in the embodiment of the present disclosure, as shown in FIG. 16, a surface of the metal bezel 203 facing the display module 204 is provided with an insulating varnish 214 (in FIG. 16, a metal bezel in the related art is on an upper side, and the metal bezel having the insulating varnish on the surface thereof of the present disclosure is on a lower side), so as to block the ESD outside the display module 204 to the maximum extent, reduce the probability that the ESD enters the display driving board 205 through the display module 204, thereby improving the ESD resistance.

Optionally, in the display apparatus provided in the embodiment of the present disclosure, as shown in FIG. 16, a surface of the metal bezel 203 away from the display module 204 is provided with an insulating varnish 214, so as to block the ESD outside the display module 204 to the maximum extent, reduce the probability that the ESD enters the display driving board 205 through the display module 204, thereby further improving the ESD resistance.

Optionally, the display apparatus provided in the embodiment of the present disclosure may further include: a conductive foam between the housing 201 and the back plate 202, which further reduces the impedance of the path through which the ESD is discharged to the housing 201 inside the display apparatus, thereby improving the ESD resistance of the complete machine.

Optionally, the display apparatus provided in the embodiment of the present disclosure may further include: a back cover which completely covers the display driving board 205 and is clamped with the metal bezel 203, wherein a surface of the back cover away from the display driving board 205 is provided with an insulating varnish, so as to block the ESD outside the back cover through the insulating varnish, and thus, realize the ESD protection for the display driving board 205.

Optionally, the display apparatus provided in the embodiment of the present disclosure may further include: an aluminum foil which completely covers the back cover, wherein a surface of the aluminum foil close to the display driving board 205 (i.e., a bottom of a side surface of the aluminum foil) is in contact with a surface of the back plate 202 away from the housing 201. With the arrangement, the ESD on the back cover can be quickly introduced to the back plate 202 through the aluminum foil, and then introduced to the housing 201 from the back plate 202 for discharging, so that a good conductive path is formed, and the ESD resistance of the complete machine is improved. In addition, the aluminum foil is also provided with an adhesive surface, so that the aluminum foil is simpler, more convenient and faster to be assembled on the back cover, thereby greatly shortening the production time, and improving the production efficiency.

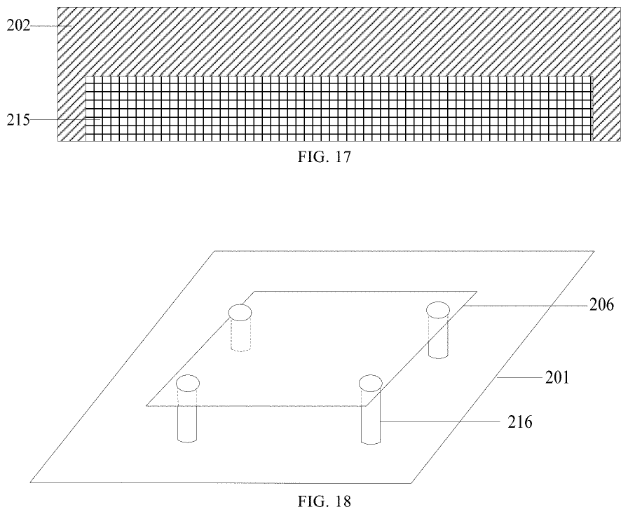

Optionally, the display apparatus provided in the embodiment of the present disclosure, as shown in FIG. 17, may further include: a second insulating mylar sheet 215 located on a side of the display driving board 205 facing the back cover. As can be seen from the above description, in the present disclosure, the insulating mylar sheets are disposed on both sides of the display driving board 205, i.e., the insulating mylar sheets include a first insulating mylar sheet (i.e., the insulating member 210) disposed between the display driving board 205 and the back plate 202, and a second insulating mylar sheet 215 disposed between the display driving board 205 and the back cover, so that the sensitive display driving board 205 can be insulated and isolated from the ESD to the maximum extent, thereby improving the ESD protection for the display apparatus. Additionally, it should be appreciated that the first insulating mylar sheet and the second insulating mylar sheet 215 are not present at a circuit interface of the display driving board 205 to facilitate plug-in

Optionally, the display apparatus provided in the embodiment of the present disclosure, as shown in FIG. 18, may further include: the system board 206 above the housing 201, and riveting columns 216 for fixing the system board 206 to the housing 201. Since a relationship of the ground wire of the system board 206 relative to the back plate 202 is equivalent to a relationship of a transmission band relative to an infinite metal board, the above equation 2 is also appropriate. According to the equation 2, if space allows, the distance h (equivalent to a height of the riveting column 216) between the ground wire of the system board 206 and the housing 201 is increased as much as possible, which is beneficial to increase the impedance of the transmission band, so that in the design, the height of the riveting column 216 is as great as possible if the space of the complete machine allows.

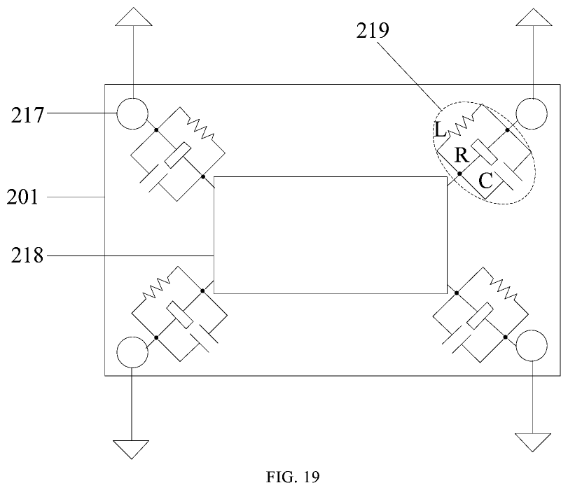

Optionally, the display apparatus provided in the embodiment of the present disclosure, as shown in FIG. 19, may further include: second conductive screws 217 for fixing the housing 201 to the back plate 202, a ground wire 218 electrically connected to the display driving board 205 and the system board 206, respectively, and electrostatic isolating devices 219, each of which is connected between a corresponding one of the second conductive screws 217 and the ground wire 218. It should be noted that the ground wire 218 electrically and respectively connected to the display driving board 205 and the system board 206 constitutes the signal ground plane of the whole display apparatus, and therefore the ground wire 218 is represented by a plane in FIG. 19.

Since the coupling path cannot be completely blocked, the main discharge path can only be changed by increasing the impedance of the transmission path. In addition to adding insulation as described above, the electrostatic isolating device 219 may be further added between the signal ground plane formed by the ground wire 218 and the housing 201 in the circuit and be configured to block the ESD interference, to prevent the ESD from being transmitted to the signal ground plane through the housing 201. In one implementation, each of the second conductive screws 217 for fixing the housing 201 to the back plate 202 is connected to the signal ground plane through a corresponding electrostatic isolating device 219, so as to achieve a good ESD protection effect.

Optionally, in the above display apparatus provided in the embodiment of the present disclosure, as shown in FIG. 19, the electrostatic isolating device 219 includes: one of a capacitor C, a resistor R and a magnetic bead L or a combination formed by any parallel connection thereof. For example, the electrostatic isolating device 219 may be formed by only the capacitor C, the resistor R or the magnetic bead L. Alternatively, the electrostatic isolating device 219 may be formed by the capacitor C and the resistor R connected in parallel, the capacitor C and the magnetic bead L connected in parallel, the resistor R and the magnetic bead L connected in parallel, or the capacitor C, the resistor R, and the magnetic bead L connected in parallel. The capacitor C, the resistor R and the magnetic bead L have the function of isolating a high-frequency ESD signal, so that the ESD signal cannot enter the signal ground plane, and thus, the influence of the ESD on signals in all paths is reduced to the maximum extent, thereby improving the ESD protection grade. Alternatively, in practice, the electrostatic isolating device 219 may also be formed by other devices having the electrostatic isolating function known to one of ordinary skill in the art, and is not specifically limited herein.

The display apparatus provided by the embodiment of the present disclosure includes: a housing; a back plate on the housing; a metal bezel clamped with the back plate at a side of the back plate; a display module and a display driving board on a side of the back plate away from the housing; wherein an insulating material layer is arranged between the back plate and the display driving board; the display module is fixed to the metal bezel through the insulating member at a side of the display module. The signal ground plane formed by the ground wire connected to the display driving board is the reference plane for signals of the whole system of the display apparatus, a certain probability of signal abnormality occurs after the reference plane is interfered, so that the static electricity grade is determined as a CLASS B, which cannot meet the current requirements, i.e., CLASS A, so that a discharge path which has the greatest influence on the determination of the static electricity grade of the complete machine is the discharge path entering the display driving board. The static electricity mainly enters the display driving board through the back plate and the display module in the related art. In the embodiment of the present disclosure, on one hand, the insulating material layer is arranged between the back plate and the display driving board, which directly increases the impedance of the path for the static electricity from the back plate to the display driving board; on the other hand, the display module and the metal bezel are fixed together by the insulating member at the side of the display module, so that the impedance of the path of the static electricity entering the display module through the metal bezel is increased, which is equivalent to indirectly increasing the impedance of the path of the static electricity entering the display driving board through the display module. Therefore, most of the static electricity is discharged through another path with a small impedance, so that the static electricity less enters the signal ground plane, thereby achieving a jitter of the ground reference plane which can be borne by a circuit, and improving the static electricity protection grade.

It will be apparent that various changes and modifications for the present disclosure may be made by one of ordinary skill in the art without departing from the spirit and scope of the present disclosure. Thus, if these changes and modifications for the present disclosure fall within the scope of the claims and their equivalents, the present disclosure is intended to also include these changes and modifications.

1. A display apparatus, comprising:
a housing;
a back plate on the housing;
a metal bezel clamped with the back plate at a side of the back plate;
a display driving board on a side of the back plate away from the housing;
an insulating material layer between the back plate and the display driving board; and
a display module on a side of the back plate away from the housing wherein a side of the display module is fixed to the metal bezel through an insulating member.

2. The display apparatus of claim 1, wherein the insulating material layer is a first insulating mylar sheet.

3. The display apparatus of claim 1, wherein the insulating member is a first conductive screw having an insulating varnish on a surface thereof.

4. The display apparatus of claim 1, wherein a surface of the housing away from the back plate is provided with an insulating varnish.

5. The display apparatus of claim 1, wherein a surface of the metal bezel facing the display module is provided with an insulating varnish.

6. The display apparatus of claim 5, wherein a surface of the metal bezel away from the display module is provided with an insulating varnish.

7. The display apparatus of claim 6, further comprising a conductive foam between the housing and the back plate.

8. The display apparatus of claim 6, further comprising a back cover which completely covers the display driving board and is clamped with the metal bezel,
wherein a surface of the back cover away from the display driving board is provided with an insulating varnish.

9. The display apparatus of claim 8, further comprising a second insulating mylar sheet on a side of the display driving board facing the back cover.

10. The display apparatus of claim 8, further comprising:
an aluminum foil which completely covers the back cover,
wherein a surface of the aluminum foil close to the display driving board is in contact with a surface of the back plate away from the housing.

11. The display apparatus of claim 6, further comprising:
a system board on the housing; and
at least one riveting column for fixing the system board to the housing.

12. The display apparatus of claim 11, further comprising:
at least one second conductive screw for fixing the housing to the back plate,
a ground wire electrically connected to the display driving board and the system board, respectively, and
at least one electrostatic isolating device connected between the at least one second conductive screw and the ground wire.

13. The display apparatus of claim 12, wherein the electrostatic isolating device comprises: one of a capacitor, a resistor and a magnetic bead or a combination formed by any parallel connection thereof.

14. The display apparatus of claim 1, further comprising:
a system board on the housing; and
at least one riveting column for fixing the system board to the housing.

15. The display apparatus of claim 2, further comprising:
a system board on the housing; and
at least one riveting column for fixing the system board to the housing.

16. The display apparatus of claim 3, further comprising:
a system board on the housing; and
at least one riveting column for fixing the system board to the housing.

17. The display apparatus of claim 4, further comprising:
a system board on the housing; and
at least one riveting column for fixing the system board to the housing.

18. The display apparatus of claim 5, further comprising:
a system board on the housing; and
at least one riveting column for fixing the system board to the housing.

19. The display apparatus of claim 18, further comprising:
at least one second conductive screw for fixing the housing to the back plate,
a ground wire electrically connected to the display driving board and the system board, respectively, and
at least one electrostatic isolating device connected between the at least one second conductive screw and the ground wire.

20. The display apparatus of claim 19, wherein the electrostatic isolating device comprises: one of a capacitor, a resistor and a magnetic bead or a combination formed by any parallel connection thereof.
